(19) United States
(12) Patent Application Publication
(10) Pub. No.: US 2026/0259285 A1
(43) Pub. Date: Sep. 3, 2026

(54) MAGNETIC RESONANCE TOMOGRAPHY DEVICE AND METHOD FOR OPERATION WITH AN UNINTERRUPTIBLE POWER SUPPLY

(71) Applicant: Siemens Healthineers AG, Forchheim (DE)

(72) Inventor: Thomas Beck, Dormitz (DE)

(21) Appl. No.: 19/553,325

(22) Filed: Feb. 28, 2026

(30) Foreign Application Priority Data
Feb. 28, 2025 (DE) 10 2025 107 700.2

(51) Int. Cl. G01R 33/28

(52) U.S. Cl. CPC G01R 33/288; G01R 33/283

(57) ABSTRACT

A magnetic resonance tomography device, a system including the magnetic resonance tomography device and an uninterruptible power supply, and a method for operation are provided. In the method, the magnetic resonance tomography device receives an item of status information of the uninterruptible power supply via the interface and ascertains a safe operating scenario as a function of the status information and an item of operating information of the magnetic resonance tomography device. A notification is output to a user for selection, an input of the user is captured, and the safe operating scenario is possibly implemented by the magnetic resonance tomography device.

This application claims the benefit of German Patent Application No. DE 10 2025 107 700.2, filed on Feb. 28, 2025, which is hereby incorporated by reference in its entirety.

### BACKGROUND

The present embodiments relate to a magnetic resonance tomography device, a system including the magnetic resonance tomography device and an uninterruptible power supply, and a method for operation of the magnetic resonance tomography device in the event of a failure of an energy supply.

Magnetic resonance tomography devices are imaging apparatuses that, in order to map an examination object, align nuclear spins of the examination object with a strong external magnetic field and excite the nuclear spins into precession about this alignment via an alternating magnetic field. The precession and/or the return of the spin from this excited state into a state with lower energy itself generates an alternating magnetic field as the response, which is received via antennas.

With the aid of magnetic gradient fields, a spatial encoding is impressed upon the signals, which subsequently makes it possible to assign the received signal to a volume element. The received signal is then evaluated, and a three-dimensional imaging representation of the examination object is provided. For receiving the signal, local receiving antennas, which are referred to as local coils, for example, are used. In order to achieve a better signal-to-noise ratio, the local coils are arranged directly on the examination object.

The energy demand of a magnetic resonance tomography device is considerable. It is necessary to cool the superconducting magnet in order to maintain the superconducting state. In operation, during image capture, beyond this, considerable currents are necessary for the resistive gradient coils and for the generation of the radio-frequency pulses for the excitation of the nuclear spins. Further, the computers require considerable electrical power for the control and the image reconstruction.

If the external power supply is interrupted, then commercially available uninterruptible power supplies only have comparatively restricted capacities. These are used in order to bring the magnetic resonance system into a safe state in a targeted manner (e.g., to shut down the magnet into a zero-field state) in order to prevent quenching. The interruption of the energy supply considerably reduces the availability of the magnetic resonance tomography device.

Independent of the grammatical term usage, individuals with male, female or other gender identities are included within the term.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a magnetic resonance tomography device and a method for operation of the magnetic resonance tomography device that increase the availability are provided.

The magnetic resonance tomography device according to the present embodiments has an interface for exchanging information with an uninterruptible power supply. This is to be understood not as the electrical connection via which the magnetic resonance tomography device draws the energy for operation of the uninterruptible power supply, but rather an interface via which the uninterruptible power supply transmits an item of status information, for example. The interface may be a wired or wireless data connection. The magnetic resonance tomography device is configured to receive an item of status information of the uninterruptible power supply via the interface, which may be that the status information of the magnetic resonance tomography device does not only arrive at the interface, but rather is also processed and/or stored for the operation of the magnetic resonance tomography device or a control of the magnetic resonance tomography device.

Status information refers to an item of information that relates to a status of the uninterruptible power supply and/or the external electrical energy supply. For example, the status information may signal the failure of the external power supply and/or indicate an available remaining amount of energy of the uninterruptible power supply.

The magnetic resonance tomography device is configured to ascertain a safe operating scenario as a function of the status information and an item of operating information of the magnetic resonance tomography device.

The operating information of the magnetic resonance tomography device indicates an item of information regarding the current state of the magnetic resonance tomography device. This may relate to a sensor value, such as a temperature of the superconducting magnet, the cooling, or the gradient coil. The operating information may also relate to a current power demand of the overall magnetic resonance tomography device and/or individual subsystems, such as the cooling or the control computer, for example. However, the operating information may also relate to an image capture that is currently taking place or is planned, such as a sequence, for example. Further, the operating information may also relate to parts of the image capture that do not relate to the energy demand of the magnetic resonance tomography device directly, but rather relate to the patient, as explained in the following.

A safe operating scenario is considered to be a sequence of control commands, which the magnetic resonance tomography device carries out or is intended to carry out. The carrying out of the control commands or the implementing of the safe operating scenario leads to the magnetic resonance tomography device and/or a patient to be examined withstanding the interruption of the external energy supply without physical harm. For example, the safe operating scenario may be the carrying out of a remaining part of an image capture or also a complete image capture and subsequent shutdown of the magnetic resonance tomography device. In one embodiment, due to the safe operating scenario, a reduced energy demand of the magnetic resonance tomography device is realized in comparison to the normal operation, at least for a predetermined time.

The magnetic resonance tomography device or its control outputs the safe operating scenario to a user via an output, such as a display. The user may then select, by way of an input, whether to have the magnetic resonance tomography device implement the safe operating scenario or whether to prevent this, for example, because the user knows about an expected end of the interruption of the energy supply. However, in one embodiment, the magnetic resonance tomography device is configured to implement the safe operating scenario autonomously.

The method according to the present embodiments is provided for operation of the method according to the present embodiments.

In one act of the method, the magnetic resonance tomography device receives an item of status information of the uninterruptible power supply via the interface. Spatially remote control computers of the magnetic resonance tomography device are also subsumed by the magnetic resonance tomography device. The statements previously made regarding the status information equally apply here.

In a further act of the method according to the present embodiments, the magnetic resonance tomography device according to the present embodiments ascertains a safe operating scenario as a function of the status information and an item of operating information of the magnetic resonance tomography device. The statements previously made regarding the operating information also accordingly apply here.

In another act of the method according to the present embodiments, a notification is output by the magnetic resonance tomography device to a user for selection on an output, such as a display.

In a further act, the magnetic resonance tomography device captures an input of the user and implements the safe operating scenario, if the user selects this. If the user makes another selection, then the magnetic resonance tomography device implements this. For example, the user may shut down the magnetic resonance tomography device even if safe operation is still conceivable for a certain time.

In another act, the magnetic resonance tomography device may also implement the safe operating scenario autonomously, without input of the user. For example, a maximum predetermined waiting time for an input of the user would be possible, for example, before the autonomous implementation begins.

In one embodiment, the magnetic resonance tomography device according to the present embodiments and the method according to the present embodiments enable safe operation with limited or interrupted external energy supply.

In an embodiment of the magnetic resonance tomography device, the status information has an item of information regarding an interrupted energy supply and/or a remaining capacity of the uninterruptible power supply. For example, the information may be that the external energy supply is interrupted or that only a maximum power is available, indicated in the information. An indication of an anticipated duration of the interruption may also be provided. Likewise, there may be an indication of the kilowatt-hours still available. The magnetic resonance tomography device is configured to ascertain a safe operating scenario as a function of the information. For example, the magnetic resonance tomography device may ascertain, based on the available remaining capacity, how long the operation may be maintained and whether an examination that has begun may be concluded; depending on this, the magnetic resonance tomography device may ascertain an ending of the examination or a shutdown of the magnetic resonance tomography device as a safe operating scenario. Further possibilities are disclosed in the following.

In one embodiment, as a function of the information, an operating scenario enables a rapid and adapted response to external events.

In a possible embodiment of the magnetic resonance tomography device, the magnetic resonance tomography device is configured to ascertain the safe operating scenario such that the safe operating scenario leads to the magnetic field of the superconducting field magnet being extended for a longer period. For example, the magnetic resonance tomography device may ascertain operating parameters that lead to an extended runtime with a predetermined amount of energy or remaining capacity still available. In one embodiment, without image capture, the magnet temperature may be increased up to close to a transition temperature of the superconducting magnet.

For example, the magnetic resonance tomography device may be configured to ascertain an energy-saving examination scenario and to complete the examination using the energy-saving examination scenario. During an image capture, the energy consumption may be reduced, for example, by a sequence being carried out with weaker gradients or a number of repetitions being reduced at the expense of a signal-to-noise ratio (SNR).

In one embodiment, in this manner, it is possible to bridge a longer energy failure, or an urgently needed examination may still be ended.

In an embodiment of the magnetic resonance tomography device, the operating information has an item of information regarding the type of ongoing examination. For example, this may be an item of information regarding whether an image capture may be interrupted without risk for the patient. While purely diagnostic image captures without intervention into the patient for the most part may be aborted unless these involve an emergency patient, image captures with or during intervention into the patient cannot be interrupted without additional risk for the patient. For example, image captures of this kind may relate to an intervention with a biopsy needle or a catheter. Image captures with a contrast agent also cannot be repeated without additional risk for the patient. In these cases, the information may also include whether the critical phase has already started (e.g., whether an instrument is already positioned inside the patient or whether the contrast agent has already been administered).

In these cases, the magnetic resonance tomography device is configured, as a function of the ongoing examination, to ascertain whether the examination may be concluded safely and then to complete the examination. In one embodiment, in this context, as described already in the preceding or in the following, the magnetic resonance tomography device ascertains a safe operating scenario for the continuation of the image capture.

In one embodiment, the magnetic resonance tomography device according to the present embodiments may thus minimize an additional risk for the patient due to the interruption of the external energy supply.

During the operation of the magnetic resonance tomography device according to the present embodiments, the method according to the present embodiments shares the advantages thereof.

### BRIEF DESCRIPTION OF THE DRAWINGS

The above-described properties, features, and advantages of this invention and the manner in which they are achieved are made more clearly and distinctly intelligible in conjunction with the following description of the example embodiments that are set out in greater detail making reference to the drawings, in which:

FIG. 1 shows a schematic representation of an example magnetic resonance tomography device; and

FIG. 2 shows a schematic flow chart for a method for operation of the magnetic resonance tomography device according to an embodiment.

### DETAILED DESCRIPTION

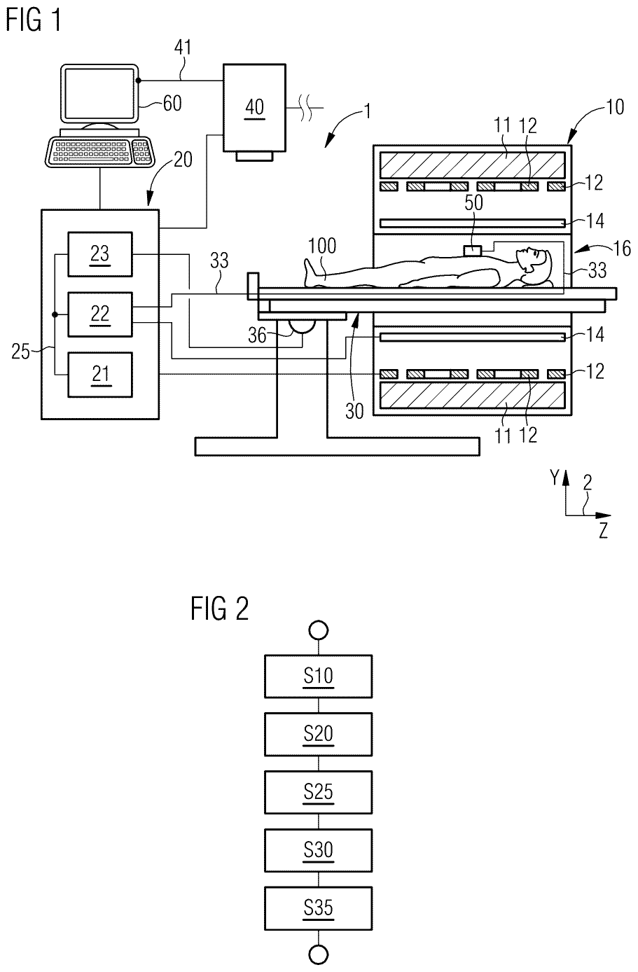

FIG. 1 shows a schematic representation of an embodiment of a magnetic resonance tomography device 1.

A magnet unit 10 has a field magnet 11 that generates a static magnetic field B0 for aligning nuclear spins of samples or of a patient 100 in a recording region. The recording region is characterized by an extremely homogenous static magnetic field B0, where the homogeneity relates, for example, to the magnetic field strength and/or the magnitude. The recording region is almost spherical and is arranged in a patient tunnel 16 that extends in a longitudinal direction 2 through the magnet unit 10. A patient couch 30 may be moved in the patient tunnel 16 by the displacement unit 36. The field magnet 11 is a superconducting field magnet that may provide magnetic fields with a magnetic flux density of up to 3 T and, in the newest devices, even higher.

In order to maintain the low temperatures of the superconducting magnetic coils, the superconducting field magnet 11 needs a cooling assembly with a high power consumption.

The magnet unit 10 further has gradient coils 12 that are configured, for spatial differentiation of the captured mapping regions in the examination volume, to overlay temporally and spatially variable magnetic fields onto the B0 magnetic field in three spatial directions. The gradient coils 12 may be coils made of normally conducting wires that may generate mutually orthogonal magnetic field gradients in the examination volume.

The resistive gradient coils 12 are also driven by a gradient control system 21 with very high currents and have a corresponding requirement for electrical energy.

The magnet unit 10 likewise has a body coil 14 that is configured to emit a radio-frequency signal fed via a signal line into the examination volume, and to receive resonance signals emitted from the patient 100 and to pass the resonance signals on via a signal line.

A control unit 20 supplies the magnet unit 10 with the different signals for the gradient coils 12 and the body coil 14 and evaluates the received signals.

Thus, the control unit 20 has a gradient controller 21 that is configured to supply the gradient coils 12 via feed lines with variable currents that provide the desired gradient fields in the examination volume in a temporally coordinated manner.

Further, the control unit 20 has a radio-frequency unit 22 that is configured to generate a radio-frequency pulse with a predetermined temporal sequence, amplitude, and spectral power distribution to excite a magnetic resonance of the nuclear spins in the patient 100. In this context, it is possible to achieve pulse powers in the kilowatt range. The excitation signals may be emitted via the body coil 14 or via a local transmitter antenna into the patient 100.

A device control 23 communicates via a signal bus 25 with the gradient control 21 and the radio-frequency unit 22.

In order to receive the magnetic resonance signal, a local coil 50 is arranged on the patient 100 in the patient tunnel 16 in order to capture magnetic resonance signals from an examination region in the immediate vicinity with the greatest possible signal-to-noise ratio. The local coil 50 is in signal connection via a connecting line 33 with a receiver in the radio-frequency unit 22.

The magnetic resonance tomography device 1 is connected to an uninterruptible power supply 40, which is configured, in the event of an interruption of an external energy supply (e.g., the power network), to maintain operation of the magnetic resonance tomography device 1 for a certain time. In one embodiment, the uninterruptible power supply 40 may maintain the operation for more than 1 minute, 10 minutes, 30 minutes, or 60 minutes. In this context, the operation may include the cooling, but also an image capture. In one embodiment, the uninterruptible power supply 40 is also configured to provide the energy supply for a complete image capture.

The magnetic resonance tomography device 1 is in signal connection with the uninterruptible power supply 40 via an interface 41, so that the uninterruptible power supply 40 may transmit an item of status information to the magnetic resonance tomography device 1. The status information has an item of information regarding the availability of the external power supply 40 and/or an available capacity of the uninterruptible power supply 40.

FIG. 2 shows a schematic flow chart of an embodiment of the method.

In act S10, the magnetic resonance tomography device 1 receives an item of status information of the uninterruptible power supply 40 via the interface 41. In this context, the magnetic resonance tomography device 1 also includes a remote control computer 60, as shown by way of example in FIG. 1. The interface 41 may be wired or also wireless. Serial protocols or also packet-oriented protocols, such as IP, may easily be used for transmission via the interface 41. The interface 41 may also be part of a data network.

The status information may relate to the availability of the external power supply (e.g., whether this has failed). However, it is also possible to indicate, for example, when an announced failure takes place, how long the failure lasts, when the external power supply is available again, or even which power may still be drawn, in the case of a power shortage. Relating to the independent power supply, it is also possible for an available remaining capacity or remaining runtime to be indicated.

In act S20, the magnetic resonance tomography device ascertains a safe operating scenario as a function of the status information and an item of operating information of the magnetic resonance tomography device 1.

The operating information may reflect the current status of the magnetic resonance tomography device 1 (e.g., the temperature of the superconducting field magnet 11), the current power demand, whether an image capture is taking place, the anticipated remaining duration thereof, or the like. However, the operating information may also relate to a patient 100 who is currently being examined. Here, it may be of importance and thus part of the operating information whether an interruption of the examination means a risk for the patient 100, whether because an emergency is involved, an intervention is taking place on the patient 100 with monitoring by the magnetic resonance tomography device 1, or the patient 100 has just received a contrast agent for the examination.

The operating scenario has at least one operating parameter, which influences an energy demand of the magnetic resonance tomography device 1 (e.g., with which the energy demand of the magnetic resonance tomography device 1 may be reduced at the point in time of step S10 receiving of the status information) if the parameter set is implemented by the control 23 of the magnetic resonance tomography device 1. For example, a cooling power may be reduced, so that a temperature of the superconducting field magnet 11 increases, but remains below a transition temperature at which the field magnet 11 quenches. The cooling power may also be controlled indirectly by a target temperature as operating parameter, which is to be set via a regulated cooling.

In one embodiment the magnetic resonance tomography device 1, in act S25, ascertains an energy-saving examination scenario as a function of the operating information. In this context, the examination scenario is part of the safe operating scenario. The examination scenario leads to it being possible to perform or finish a planned examination scenario with a lower energy demand, compared to a sequence that is predetermined for the examination scenario without an item of status information regarding a reduced availability of the external energy supply. This may, for example, relate to a reduced gradient field strength, a reduced radio-frequency power and/or a reduced number of repetitions of a subsequence. When finishing an examination, a reduced image quality may also be acceptable in this context.

The operating scenario is safe in that a risk of harm to the magnetic resonance tomography device 1 is not or only minimally increased due to the operation according to the operating scenario. For example, a health risk for the patient 100 is not increased by the safe operating scenario. This may also relate to an intervention into the patient 100 with use of the magnetic resonance tomography device 1, by the intervention being able to be carried out or concluded successfully and thus by being able to avoid a repeat intervention, such as in the case of a needle biopsy or an image capture with administration of contrast agent, for example.

In a further act S30, a notification is output to a user for selection (e.g., a selection menu on a display), and an input of the user is captured. In one embodiment, for example, the user may select between a safe operating scenario for continuing the operation or an operational readiness, and an immediate controlled shutdown. The magnetic resonance 1 or its control 23 implements the safe operating scenario following selection by the user, by the corresponding operating parameters being set. In this context, the control 23 may implement the safe operating scenario autonomously if no input by the user takes place within a predetermined time.

In this context, in one embodiment, as part of act S30, also in subact S35, the examination scenario with the carrying out of an examination corresponding to the parameters of the examination scenario is carried out by the magnetic resonance tomography device or its control 23.

In a possible embodiment of the method, the status information has an item of information regarding an interrupted energy supply and/or a remaining capacity of the uninterruptible power supply. In act S20, in this context, the safe operating scenario is ascertained by the magnetic resonance tomography device as a function of the remaining capacity. For example, in the case of a low remaining capacity, further examinations are prevented from being carried out by the control 23 with the safe operating scenario, while in the case of greater remaining capacity, the safe operating scenario may also include the carrying out of an examination.

Although the invention has been illustrated and described in detail with the example embodiments, the invention is not restricted by the examples disclosed, and other variations may be derived therefrom by a person skilled in the art without departing from the protective scope of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnetic resonance tomography device comprising:
an interface for an uninterruptible power supply, the interface being configured to receive an item of status information of the uninterruptible power supply,
wherein the magnetic resonance tomography device is configured to:
ascertain a safe operating scenario as a function of the item of status information and an item of operating information of the magnetic resonance tomography device; and
output the item of operating information to a user for selection, autonomously implement the item of operating information, or output the item of operating information to the user for selection and autonomously implement the item of operating information.

2. The magnetic resonance tomography device of claim 1, wherein the item of status information has an item of information regarding an interrupted energy supply, a remaining capacity of the uninterruptible power supply, or the item of information regarding the interrupted energy supply and the remaining capacity of the uninterruptible power supply, and
wherein the magnetic resonance tomography device is configured to ascertain a safe operating scenario as a function of the item of status information.

3. The magnetic resonance tomography device of claim 1, wherein the magnetic resonance tomography device is configured to ascertain the safe operating scenario such that the safe operating scenario leads to the magnetic field being extended for a longer period.

4. The magnetic resonance tomography device of claim 1, wherein the magnetic resonance tomography device is configured to:
ascertain an energy-saving examination scenario; and
complete an examination using the energy-saving examination scenario.

5. The magnetic resonance tomography device of claim 4, wherein the item of operating information has an item of information regarding a type of ongoing examination, and
wherein the magnetic resonance tomography device is configured, as a function of the ongoing examination, to:
ascertain whether the examination is concludable safely; and
when the examination is ascertained as being concludable safely, complete the examination.

6. A system comprising:
a magnetic resonance tomography device comprising:
an interface for an uninterruptible power supply, the interface being configured to receive an item of status information of the uninterruptible power supply, wherein the magnetic resonance tomography device is configured to ascertain a safe operating scenario as a function of the item of status information and an item of operating information of the magnetic resonance tomography device, and output the item of operating information to a user for selection, autonomously implement the item of operating information, or output the item of operating information to the user for selection and autonomously implement the item of operating information; and
an uninterruptible power supply,
wherein the magnetic resonance tomography device and the uninterruptible power supply are in signal connection via the interface, and
wherein the uninterruptible power supply is configured to transmit an item of status information to the magnetic resonance tomography device via the interface.

7. A method for operating a system, the method comprising:
receiving an item of status information of an uninterruptible power supply of the system via an interface of a magnetic resonance tomography device of the system;
ascertaining a safe operating scenario as a function of the item of status information and an item of operating information of the magnetic resonance tomography device; and
outputting a notification to a user for selection, capturing an input, and implementing the safe operating scenario via the magnetic resonance tomography device, or autonomously implementing the safe operating scenario via the magnetic resonance tomography device.

8. The method of claim 7, wherein the item of status information has an item of information regarding an interrupted energy supply, a remaining capacity of the uninterruptible power supply, or the item of information regarding the interrupted energy supply and the remaining capacity of the uninterruptible power supply, and
wherein the method further comprises ascertaining a safe operating scenario via the magnetic resonance tomography device as a function of the remaining capacity.

9. The method of claim 7, wherein the item of operating information has an item of information regarding a type of ongoing examination,
wherein the method further comprises:
ascertaining, by the magnetic resonance tomography device, as a function of the ongoing examination, whether the examination is concludable safely; and
when it is ascertained the examination is concludable safely, completing the examination; and
when it is ascertained the examination cannot be concludable safely, aborting the examination.

10. The method of claim 9, further comprising:
ascertaining, by the magnetic resonance tomography device, an energy-saving examination scenario; and
completing the examination using the energy-saving examination scenario.
